(19) United States
(12) Patent Application Publication
(10) Pub. No.: US 2015/0303209 A1
(43) Pub. Date: Oct. 22, 2015

(54) THREE-DIMENSIONAL SEMICONDUCTOR DEVICES INCLUDING A CONNECTION REGION

(71) Applicants: Jintaek PARK, Hwaseong-si (KR); Yoocheol Shin, Hwaseong-si (KR); Youngwoo Park, Seoul (KR)

(72) Inventors: Jintaek PARK, Hwaseong-si (KR); Yoocheol Shin, Hwaseong-si (KR); Youngwoo Park, Seoul (KR)

(21) Appl. No.: 14/656,115

(22) Filed: Mar. 12, 2015

(30) Foreign Application Priority Data
Apr. 22, 2014 (KR) 10-2014-0048124

(51) Int. Cl. H01L 27/115; H01L 27/112

(52) U.S. Cl. CPC H01L 27/11556; H01L 27/11286

(57) ABSTRACT

Semiconductor devices and methods of forming the semiconductor devices are provided. The semiconductor devices may include a peripheral circuit part that is disposed under a cell array circuit part. The peripheral circuit part may drive the cell array circuit part. The semiconductor devices may also include first conductive lines, which are connected to the peripheral circuit part, and second conductive lines, which are connected to the cell array circuit part. The first conductive lines and the second conductive lines may have substantially the same shape, and the first conductive lines may overlap with the second conductive lines in a connection region, respectively.

### CROSS-REFERENCE TO RELATED APPLICATION

This U.S. non-provisional patent application claims priority under 35 U.S.C. §119 to Korean Patent Application No. 10-2014-0048124, filed on Apr. 22, 2014, in the Korean Intellectual Property Office, the disclosure of which is hereby incorporated by reference in its entirety.

### BACKGROUND

The inventive concept generally relates to the field of electronics and, more particularly, to semiconductor devices.

A three-dimensional integrated circuit (3D-IC) memory technique has been developed to increase memory capacity of a semiconductor memory device. The 3D-IC memory technique includes a variety of methods for arranging memory cells three-dimensionally. As well as the 3D-IC memory technique, a patterning technique for fine patterns and a multi-level cell (MLC) technique may be used to increase the memory capacity of the semiconductor memory device. However, the patterning technique for the fine patterns may be very expensive, and the MLC technique may not be suitable to increase the number of bits per a unit cell. Thus, the 3D-IC memory technique may be important to increase the memory capacity. In addition, if the patterning technique for the fine patterns and the MLC technique are combined with the 3D-IC memory technique, the memory capacity may more increas. Thus, the patterning technique for the fine patterns and the MLC technique may be developed independently of the 3D-IC memory technique.

### SUMMARY

Some embodiments of the inventive concept may provide highly integrated semiconductor devices.

Embodiments of the inventive concept may provide a semiconductor device including: a substrate comprising a circuit region and a first connection region disposed at a side of the circuit region; a peripheral circuit part disposed on the substrate in the circuit region; first conductive lines electrically connected to the peripheral circuit part and extending into the first connection region; a cell array circuit part disposed on the peripheral circuit part; second conductive lines electrically connected to the cell array circuit part and disposed above the first conductive lines; and first conductive contacts connecting the second conductive lines to the first conductive lines, respectively. The first conductive lines may have the substantially same shapes as and overlap with the second conductive lines in the first connection region, respectively, when viewed from a plan view.

In some embodiments, the cell array circuit part may include: a semiconductor layer insulated from the peripheral circuit part; active pillars protruding from the semiconductor layer; and word lines adjacent to a sidewall of each of the active pillars, the word lines extending in a direction intersecting the second conductive lines. The second conductive lines may be bit lines electrically connected to top ends of the active pillars.

In some embodiments, the semiconductor device may further include: a first interlayer insulating layer covering a sidewall of the cell array circuit part and the first conductive lines. The first conductive contacts may penetrate the first interlayer insulating layer.

In some embodiments, the semiconductor device may further include: a second interlayer insulating layer covering the active pillars and the first interlayer insulating layer, the second interlayer insulating layer thinner than the first interlayer insulating layer; and second conductive contacts penetrating the second interlayer insulating layer to connect the first conductive contacts to the second conductive lines, respectively. Widths of the second conductive contacts may be smaller than widths of the first conductive contacts.

In some embodiments, the semiconductor device may further include: a second interlayer insulating layer disposed between the semiconductor layer and the first conductive lines and between the first interlayer insulating layer and the first conductive lines; and second conductive contacts penetrating the second interlayer insulating layer to connect the first conductive contacts to the first conductive lines, respectively. Widths of the second conductive contacts may be smaller than widths of the first conductive contacts.

In some embodiments, the semiconductor device may further include: conductive pads disposed between the second conductive contacts and the first conductive contacts, respectively. Widths of the conductive pads may be greater than the widths of the first conductive contacts.

In some embodiments, the first conductive lines may have the substantially same width as the second conductive lines.

In some embodiments, one of the first conductive lines may laterally protrude more than another, adjacent to the one, from among the first conductive lines, and one of the second conductive lines may laterally protrude more than another, adjacent to the one, from among the second conductive lines.

In some embodiments, widths of end portions of the first and second conductive lines may be greater than widths of line portions of the second conductive lines.

In some embodiments, the substrate may further include: a second connection region disposed at another side of the circuit region. The second connection region may be opposite to the first connection region with the circuit region therebetween. Some of the end portions of the first and second conductive lines may be disposed above the substrate of the first connection region, and others of the end portions of the first and second connection lines may be disposed above the substrate of the second connection region.

In some embodiments, the semiconductor device may further include: a dummy conductive line disposed between the second conductive lines adjacent to each other. The dummy conductive line may be parallel to the second conductive lines.

In some embodiments, some and others of the first and second conductive lines may be symmetric in the first connection region.

### BRIEF DESCRIPTION OF THE DRAWINGS

FIG. 1 is a circuit diagram of a semiconductor device according to example embodiments of the inventive concept.

FIG. 2A is a plan view illustrating a semiconductor device according to some embodiments of the inventive concept.

FIG. 2B is a cross-sectional view taken along the line A-A′ of FIG. 2A.

FIGS. 3A, 4A, 5A, 6A, 7A, 8A, 9A, 10A and 11A are plan views illustrating a method of fabricating the semiconductor device of FIG. 2A.

FIGS. 3B, 4B, 5B, 6B, 7B, 8B, 9B, 10B and 11B are cross-sectional views, taken along the line A-A′ of FIG. 2A, illustrating a method of fabricating the semiconductor device.

FIG. 12A is a plan view illustrating a semiconductor device according to some embodiments of the inventive concept.

FIG. 12B is a cross-sectional view taken along the line A-A′ of FIG. 12A.

FIG. 13A is a plan view illustrating a semiconductor device according to some embodiments of the inventive concept.

FIG. 13B is a cross-sectional view taken along the line A-A′ of FIG. 13A.

FIG. 14 is a plan view illustrating a semiconductor device according to some embodiments of the inventive concept.

FIG. 15 is a plan view illustrating a semiconductor device according to some embodiments of the inventive concept.

FIG. 16 is a schematic block diagram illustrating a memory system including a semiconductor device according to embodiments of the inventive concept.

FIG. 17 is a schematic block diagram illustrating a memory card including a semiconductor device according to embodiments of the inventive concept.

FIG. 18 is a schematic block diagram illustrating an information processing system including a semiconductor device according to embodiments of the inventive concept.

### DETAILED DESCRIPTION

The inventive concept will now be described more fully hereinafter with reference to the accompanying drawings, in which some embodiments of the inventive concept are shown. The advantages and features of the inventive concept and methods of achieving them will be apparent from the following some embodiments that will be described in more detail with reference to the accompanying drawings. It should be noted, however, that the inventive concept is not limited to the following some embodiments, and may be implemented in various forms. Accordingly, the some embodiments are provided only to disclose the inventive concept and let those skilled in the art know the category of the inventive concept. In the drawings, embodiments of the inventive concept are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal views of the inventive concept. Accordingly, shapes of the views may be modified according to manufacturing techniques and/or allowable errors. Therefore, the embodiments of the inventive concept are not limited to the specific shape illustrated in the views, but may include other shapes that may be created according to manufacturing processes. Areas exemplified in the drawings have general properties, and are used to illustrate specific shapes of elements. Thus, this should not be construed as limited to the scope of the inventive concept.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Some embodiments of aspects of the present inventive concept explained and illustrated herein include their complementary counterparts. The same reference numerals or the same reference designators denote the same elements throughout the specification.

Moreover, some embodiments are described herein with reference to cross-sectional illustrations and/or plane illustrations that are idealized illustrations. Accordingly, variations from the shapes of the illustrations as a result, for example, of manufacturing techniques and/or tolerances, are to be expected. Thus, embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

As appreciated by the present inventive entity, devices and methods of forming devices according to various embodiments described herein may be embodied in microelectronic devices such as integrated circuits, wherein a plurality of devices according to various embodiments described herein are integrated in the same microelectronic device. Accordingly, the cross-sectional view(s) illustrated herein may be replicated in two different directions, which need not be orthogonal, in the microelectronic device. Thus, a plan view of the microelectronic device that embodies devices according to various embodiments described herein may include a plurality of the devices in an array and/or in a two-dimensional pattern that is based on the functionality of the microelectronic device.

The devices according to various embodiments described herein may be interspersed among other devices depending on the functionality of the microelectronic device. Moreover, microelectronic devices according to various embodiments described herein may be replicated in a third direction that may be orthogonal to the two different directions, to provide three-dimensional integrated circuits.

Accordingly, the cross-sectional view(s) illustrated herein provide support for a plurality of devices according to various embodiments described herein that extend along two different directions in a plan view and/or in three different directions in a perspective view. For example, when a single active region is illustrated in a cross-sectional view of a device/structure, the device/structure may include a plurality of active regions and transistor structures (or memory cell structures, gate structures, etc., as appropriate to the case) thereon, as would be illustrated by a plan view of the device/structure.

Hereinafter, some embodiments of the inventive concept will be described in detail with reference to the drawings. A non-volatile memory device according to some embodiments of the inventive concept may have a structure of a three-dimensional (3D) semiconductor memory device.

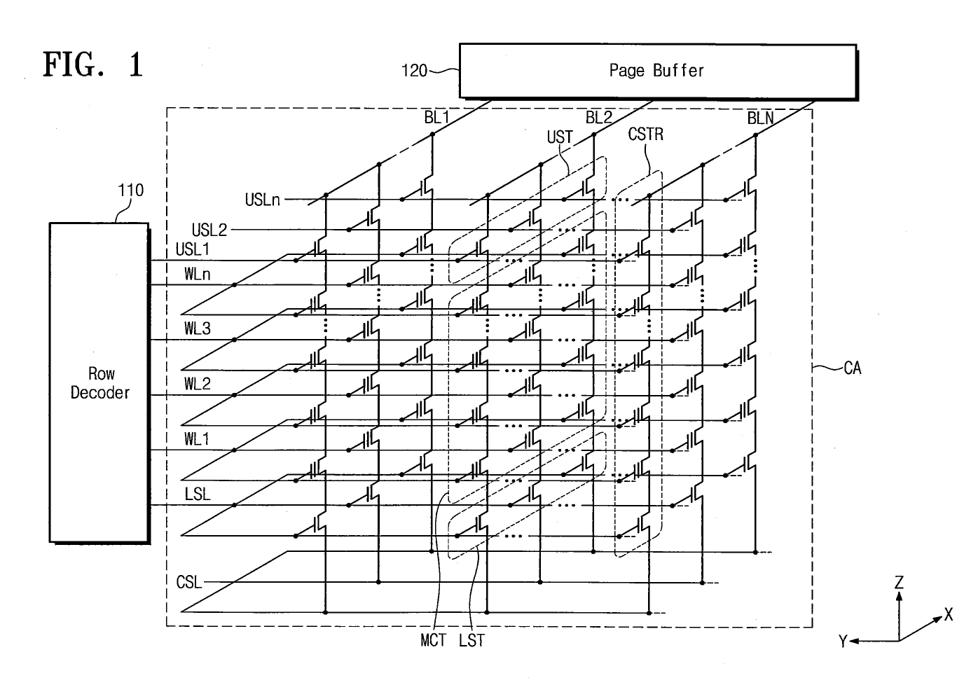

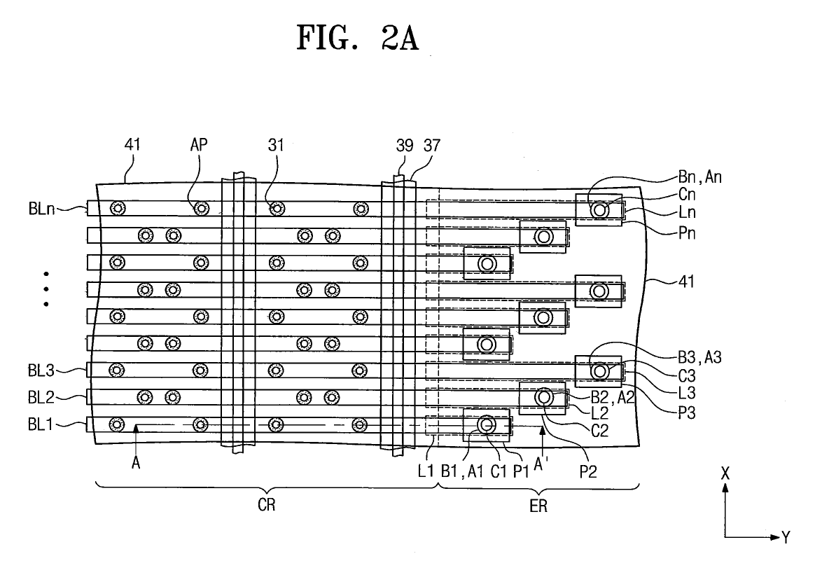

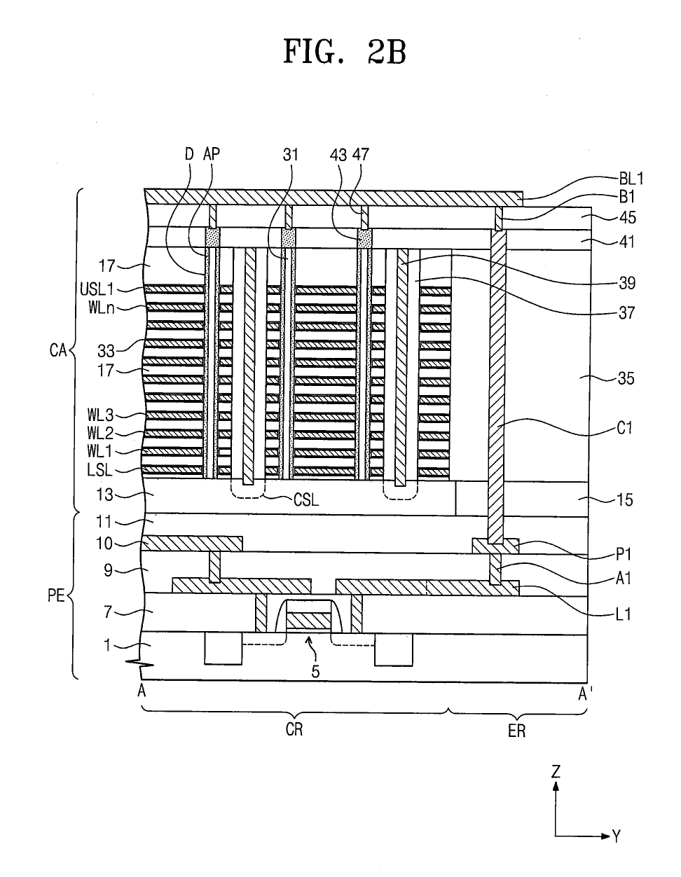

FIG. 1 is a circuit diagram of a semiconductor device according to example embodiments of the inventive concept. FIG. 2A is a plan view illustrating a semiconductor device according to some embodiments of the inventive concept. FIG. 2B is a cross-sectional view taken along the line A-A′ of FIG. 2A.

Referring to FIGS. 1, 2A, and 2B, a vertical semiconductor memory device according to some embodiments may include a substrate 1. The substrate 1 may include a circuit region CR and a connection region ER disposed at a side of one edge of the circuit region CR. A peripheral circuit part PE and a cell array circuit part CA are sequentially stacked on the substrate 1 of the circuit region CR. The peripheral circuit part PE may include at least a page buffer 120. In addition, the peripheral circuit part PE disposed under the cell array circuit part CA may further include a row decoder 110. However, the inventive concept is not limited thereto. In some embodiments, the row decoder 110 may be disposed on a sidewall of the cell array circuit part CA, not under the cell array circuit part CA. The peripheral circuit part PE may include at least one of a plurality of peripheral circuit transistors 5 and peripheral circuit interconnections 10 constituting the row decoder 110 and first to third interlayer dielectric layers 7, 9, and 11 covering the peripheral circuit transistors 5 and the peripheral circuit interconnections 10.

The cell array circuit part CA may include a common source line CSL, a plurality of bit lines BL1, BL2, . . . , and BLn, and a plurality of cell strings CSTR disposed between the common source line CSL and the bit lints BL1 to BLn.

The common source line CSL may be a dopant injection region disposed in a semiconductor layer 13. The bit lines BL1 to BLn may be disposed above the semiconductor layer 13. The bit lines BL1 to BLn may be arranged two-dimensionally. A plurality of cell strings CSTR may be connected in parallel to each of the bit lines BL1 to BLn, Thus, the cell strings CSTR may be two-dimensionally arranged on the semiconductor layer 13.

Each of the cell strings CSTR may include a lower selection transistor LST connected to the common source line CSL, an upper selection transistor UST connected to one of the bit lines BL1 to BLn, and a plurality of memory cell transistors MCT disposed between the lower and upper selection transistors LST and UST. The lower selection transistor LST, the memory cell transistors MCT, and the upper selection transistor UST may be connected in series to one another. A lower selection line LSL, a plurality of word lines WL1, WL2, . . . , and WLn, and upper selection lines USL1, USL2, . . . , and USLn which are disposed between the common source lines CSL and the bit lines BL1 to BLn may be used as gate electrodes of the lower selection transistor LST, the memory cell transistors MCT, and the upper selection transistors UST, respectively. The common source lines CSL, the lower selection line LSL, the word lines WL1 to WLn, and the upper selection lines USL1 to USLn may extend in a first direction X. The bit lines BL1 to BLn may extend in a second direction Y intersecting the first direction X. A third direction Z may be substantially perpendicular to the first direction X and the second direction Y.

Distances of the lower selection transistors LST from the semiconductor layer 13 may be substantially equal to one another. Gate electrodes of the lower selection transistors LST may be at an equipotential state because they are connected in common to the lower selection line LSL. Likewise, gate electrodes of the memory cell transistors MCT disposed at a substantially same distance from the common source line CSL may be connected in common to one of the word lines WL1 to WLn, so they may be at an equipotential state. Since one cell string CSTR includes the plurality of memory cell transistors MCT respectively disposed at different distances from the common source line CSL, the plurality of word lines WL1 to WLn may be sequentially stacked between the common source line CSL and the bit lines BL1 to BLn.

Each of the cell strings CSTR may include an active pillar AP that vertically extends from the semiconductor layer 13 so as to be connected to one of the bit lines BL1 to BLn. The active pillar AP may be formed to penetrate each upper selection line USL1, USL2, . . . , or USLn, the word lines WL1 to WLn, and the lower selection line LSL. The upper selection lines USL1 to USLn, the word lines WL1 to WLn, and the lower selection line LSL may be electrically connected to the row decoder 110. The row decoder 110 may apply voltages to the upper selection lines USL1 to USLn, the word lines WL1 to WLn, and the lower selection line LSL, respectively.

A gate dielectric layer 33 may be disposed between the active pillar AP and the lines USL1 to USLn, WL1 to WLn, and LSL. In some embodiments, the gate dielectric layer 33 may include at least one of a tunnel dielectric layer, a charge storage layer, or a blocking dielectric layer. In some embodiments, the charge storage layer may not exist between the active pillar AP and the lower selection line LSL and/or between the active pillar AP and the upper selection lines USL1 to USLn. A common drain region D may be disposed in a top end portion of the active pillar AP.

The lower and upper selection transistors LST and UST and the memory cell transistors MCT may be metal-oxide-semiconductor (MOS) field effect transistors using the active pillar AP as channel regions. The active pillar AP may be formed of an undoped poly-silicon layer or an undoped semiconductor layer. The active pillar AP may have a cup shape. An inner space of the active pillar AP may be filled with a first filling insulation pattern 31.

Intergate insulating layers 17 may be disposed between the word line WLn and the upper selection lines USL1 to USLn, between the word lines WL1 to WLn, and between the word line WL1 and the lower selection line LSL. The intergate insulating layers 17 may further include an uppermost intergate insulating layer 17 disposed on top surfaces of the upper selection lines USL1 to USLn and a lowermost intergate insulating layer 17 disposed under bottom surfaces of the lower selection lines LSL. The lower selection line LSL, the word lines WL1 to WLn, and each upper selection line USL1, USL2, . . . , or USLn which are sequentially stacked may constitute a stack structure. A plurality of the stack structures may be disposed on the semiconductor layer 13. The stack structures may be laterally spaced apart from each other. A second filling insulation pattern 37 may be disposed between the stack structures adjacent to each other. A common source interconnection 39 may be disposed in the second filling insulation pattern 37 so as to be in contact with the common source line CSL.

The semiconductor layer 13, the peripheral circuit part PE, and the cell array circuit part CA may be disposed on the substrate 1 of the circuit region CR. A fourth interlayer insulating layer 15 may be disposed in the connection region ER. The fourth interlayer insulating layer 15 may cover a sidewall of the semiconductor layer 13 and a top surface of the third interlayer insulating layer 11 disposed in the connection region ER. A fifth interlayer insulating layer 35 may be disposed on the fourth interlayer insulating layer 15. The fifth interlayer insulating layer 35 may cover sidewalls of the lower selection lines LSL, sidewalls of the word lines WL1 to WLn, sidewalls of the upper selection lines USL1 to USLn, and sidewalls of the intergate insulating layers 17. In some embodiments, end portions of the lower selection line LSL, the word lines WL1 to WL2, and each upper selection line USL1, USL2, . . . , or USLn which are included in one stack structure may constitute a stepped structure.

Top surfaces of the uppermost intergate insulating layer 17, the fifth interlayer insulating layer 35, the active pillar AP, the first filling insulation pattern 31, the second filling insulation pattern 37, and the common source interconnection 39 may be coplanar with one another and may be covered with a sixth interlayer insulating layer 41. An active plug 43 may penetrate the sixth interlayer insulating layer 41 so as to be in contact with the top surface of each of the active pillars AP in the circuit region CR. A seventh interlayer insulating layer 45 may be disposed on the sixth interlayer insulating layer 41. In some embodiments, the sixth interlayer insulating layer 41 may be thinner than the fifth interlayer insulating layer 35. In some embodiments, the seventh interlayer insulating layer 45 may also be thinner than the fifth interlayer insulating layer 35.

A bit line contact 47 may penetrate (i.e., pass through) the seventh interlayer insulating layer 45 so as to be connected to each of the active plugs 43 in the circuit region CR. The bit lines BL1 to BLn may be disposed on the seventh interlayer insulating layer 45 and may be connected to the bit line contacts 47. An end portion of each of the bit lines BL1 to BLn may extend onto the seventh interlayer insulating layer 45 disposed in the connection region ER and may be electrically connected to the page buffer 120 of the peripheral circuit part PE. The page buffer 120 may apply a voltage to each of the bit lines BL1 to BLn and may sense data from each of the bit lines BL1 to BLn. The page buffer 120 may include a plurality of connection lines L1 to Ln extending from the circuit region CR into the connection region ER. When viewed from a plan view, portions, disposed in the connection region ER, of the connection lines L1 to Ln may have the substantially same shapes as portions, disposed in the connection region ER, of the bit lines BL1 to BLn, respectively. In addition, the portions of the connection lines L1 to Ln may overlap with the portions of the bit lines BL1 to BLn in the connection region ER, respectively. In the present specification, the phrase “the substantially same shape” may mean the substantially same form, the substantially same length, and/or the substantially same width. The connection lines L1 to Ln may have the substantially same width as the bit lines BL1 to BLn. In some embodiments, when viewed from a plan view, portions, disposed in the connection region ER, of the connection lines L1 to Ln and portions, disposed in the connection region ER, of the bit lines BL1 to BLn may have substantially equal shapes, respectively. The connection lines L1 to Ln and the bit lines BL1 to BLn may have substantially equal widths.

The connection lines L1 to Ln may be electrically connected to the bit lines BL1 to BLn through lower assistant connection contacts A1 to An, connection pads P1 to Pn, deep connection contacts C1 to Cn, and upper assistant connection contacts B1 to Bn, respectively. The lower assistant connection contacts A1 to An may penetrate (i.e., pass through) the second interlayer insulating layer 9. The connection pads P1 to Pn may be disposed between the second interlayer insulating layer 9 and the third interlayer insulating layer 11. The deep connection contacts C1 to Cn may penetrate (i.e., pass through) the third to sixth interlayer insulating layers 11, 15, 35, and 41. The upper assistant connection contacts B1 to Bn may penetrate (i.e., pass through) the seventh interlayer insulating layer 45. A vertical length of the deep connection contacts C1 to Cn may be greater than vertical lengths of the lower and upper assistant connection contacts A1 to An and B1 to Bn. A width of the deep connection contacts C1 to Cn may be greater than widths of the lower and upper assistant connection contacts A1 to An and B1 to Bn. A width of the connection pads P1 to Pn may be greater than the width of the deep connection contacts C1 to Cn.

Positions of the end portions of the bit lines BL1 to BLn may be different from one another in the connection region ER. In more detail, positions of the end portions first to third bit lines BL1 to BL3 adjacent to one another may be different from one another. In other words, when viewed from a plan view, the end portions of the first, second, and third bit lines BL1, BL2, and BL3 may protrude from the circuit region CR in the second direction Y and may have first, second, and third protruding lengths from the circuit region CR, respectively. The first, second, and third protruding lengths of the end portions of the first to third bit lines BL1 to BL3 may be different from one another. In some embodiments, among the first to third protruding lengths, the first protruding length may be the minimum and the third protruding length may be the maximum. The second protruding length may be greater than the first protruding length and smaller than the third protruding length. That is, the protruding lengths of the end portions of the three adjacent bit lines BL1 to BL3 may progressively (i.e., monotonically) increase along the first direction X. Distances between the lower assistant connection contacts A1 to An may increase by the arrangement of the end portions of the bit lines BL1 to BLn. Likewise, distances between the upper assistant connection contacts B1 to Bn may increase, and distances between the deep connection contacts C1 to Cn may also increase. In addition, distances between the connection pads P1 to Pn may increase. As a result, a process margin (e.g., a margin of a photolithography process) may increase to reduce or possibly minimize or prevent a bridge problem that may be caused by misalignment. In some embodiments, the three adjacent bit lines BL1 to BL3 having the end portions described above may be repeatedly arranged along the first direction X.

In some embodiments, the aforementioned arrangement manner of the end portions may be applied to two adjacent bit lines or four or more adjacent bit lines. In some embodiments, if the two adjacent bit lines are repeatedly arranged in the first direction X, a protruding length in the second direction Y of one of the two adjacent bit lines may be greater than that of another of the two adjacent bit lines. In some embodiments, if the four or more adjacent bit lines are repeatedly arranged in the first direction X, protruding lengths in the second direction Y of the four or more adjacent bit lines may progressively (i.e., monotonically) increase along the first direction X.

As described above, the peripheral circuit part PE for driving the cell array circuit part CA may be disposed under the cell array circuit part CA, thereby improving an integration degree of the semiconductor device. In addition, the connection lines L1 to Ln connected to the peripheral circuit part PE may have the same shapes as and may overlap with the bit lines BL1 to BLn connected to the cell array circuit part CA over the substrate 1 of the connection region ER, respectively, when viewed from a plan view. Thus, the connection contacts A1 to An, B1 to Bn, C1 to Cn, and the connection pads P1 to Pn connected therebetween may be easily arranged and/or formed. In other words, since the portions, which are disposed in the connection region ER, of the connection lines L1 to Ln have the same shapes as the portions, which are disposed in the connection region ER, of the bit lines BL1 to BLn, the portion of the connection lines L1 to Ln may be easily connected to the portions of the bit lines BL1 to BLn. As a result, highly integrated semiconductor devices may be easily realized.

Now will be described a method of fabricating the semiconductor device according to some embodiments of the inventive concept.

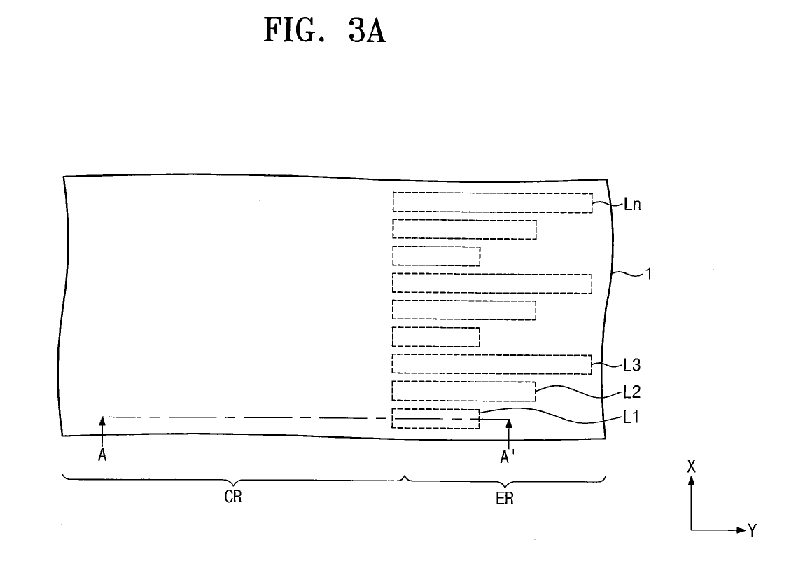

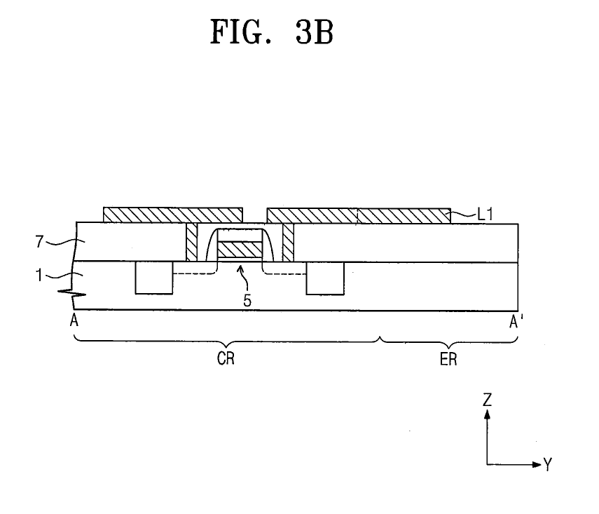

FIGS. 3A, 4A, 5A, 6A, 7A, 8A, 9A, 10A and 11A are plan views illustrating a method of fabricating the semiconductor device of FIG. 2A. FIGS. 3B, 4B, 5B, 6B, 7B, 8B, 9B, 10B and 11B are cross-sectional views, taken along the line A-A′ of FIG. 2A, illustrating a method of fabricating the semiconductor device.

Referring to FIGS. 3A and 3B, a substrate 1 including a circuit region CR and a connection region ER may be prepared. The substrate 1 may be a semiconductor substrate. For example, the substrate 1 may be a silicon single-crystalline wafer or a silicon-on-insulator (SOI) substrate. A plurality of peripheral circuit transistors 5 may be formed on the substrate 1 in the circuit region CR. A first interlayer insulating layer 7 may be formed to cover the peripheral circuit transistors 5. Connection lines L1 to Ln may be formed on the first interlayer insulating layer 7. The connection lines L1 to Ln may be electrically connected to the peripheral circuit transistors 5 and may laterally extend into the connection region ER.

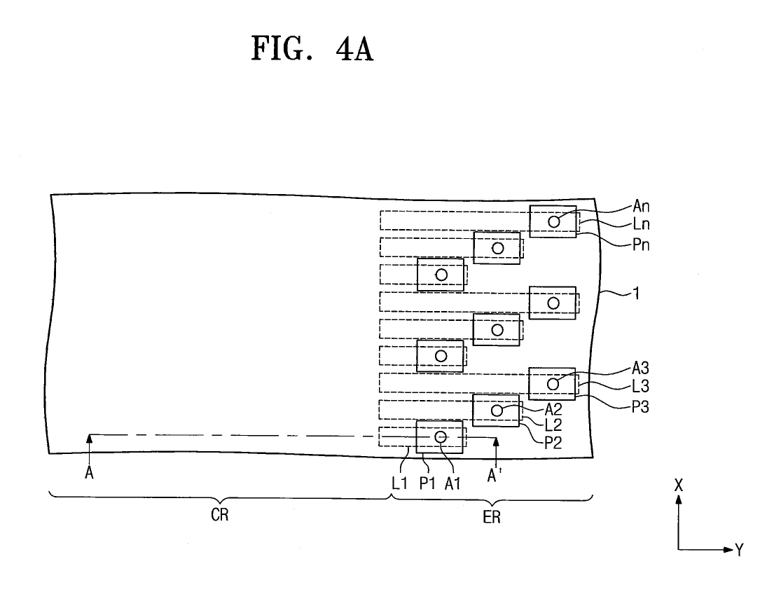

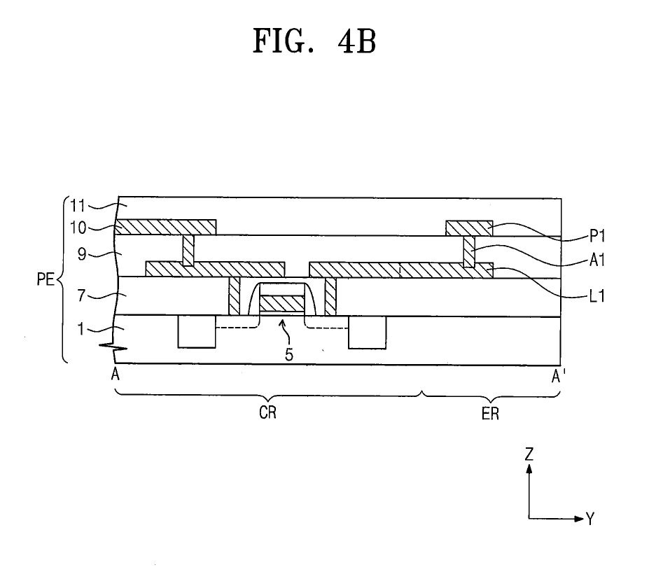

Referring to FIGS. 4A and 4B, a second interlayer insulating layer 9 may be formed to cover the connection lines L1 to Ln and the first interlayer insulating layer 7. Lower assistant connection contacts A1 to An may be formed to penetrate the second interlayer insulating layer 9. The lower assistant connection contacts A1 to An are connected to the connection lines L1 to Ln, respectively. Connection pads P1 to Pn may be formed on the second interlayer insulating layer 9 so as to be connected to the lower assistant connection contacts A1 to An. While, the connection lines L1 to Ln, the lower assistant connection contacts A1 to An, and the connection pads P1 to Pn are formed, peripheral circuit interconnections 10 may be formed in the circuit region CR. In some embodiments, the connection lines L1 to Ln, the lower assistant connection contacts A1 to An, the connection pads P1 to Pn and the peripheral circuit interconnections 10 may be formed concurrently or simultaneously. The peripheral circuit interconnections 10 may be electrically connected to the peripheral circuit transistors 5. A third interlayer insulating layer 11 may be formed to cover the connection pads P1 to Pn, the peripheral circuit interconnections 10, and the second interlayer insulating layer 9. As a result, a peripheral circuit part PE may be formed.

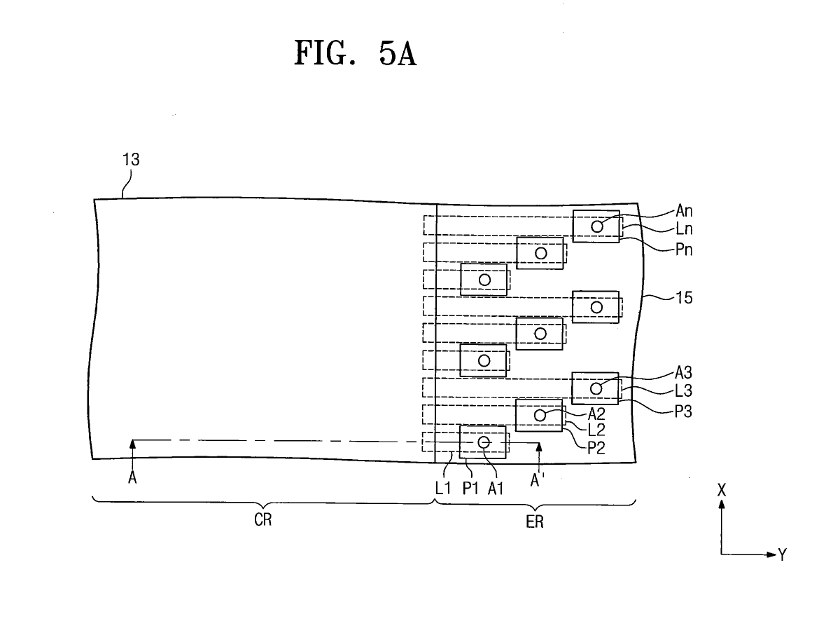

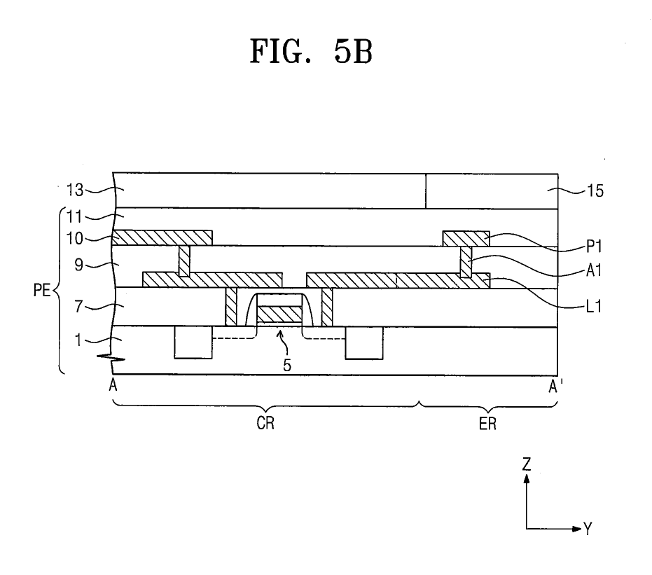

Referring to FIGS. 5A and 5B, a semiconductor layer 13 may be formed on the third interlayer insulating layer 11 of the peripheral circuit part PE. For example, the semiconductor layer 13 may be a silicon epitaxial layer and may have a silicon single-crystalline structure. In some embodiments, a contact hole may be formed to penetrate the first to third interlayer insulating layers 7, 9, and 11. The contact hole may expose the substrate 1. Thereafter, the semiconductor layer 13 may be formed using a selective epitaxial growth (SEG) or a solid phase epitaxial (SPE) method to fill the contact hole and cover the third interlayer insulating layer 11. The semiconductor layer 13 disposed in the contact hole may be removed, and then, the contact hole may be filled with an insulating layer. In some embodiments, the semiconductor layer 13 may be formed of a poly-silicon layer. The semiconductor layer 13 disposed in the connection region ER may be removed to expose the third interlayer insulating layer 11. Subsequently, a fourth interlayer insulating layer 15 may be formed on the third interlayer insulating layer 11 in the connection region ER.

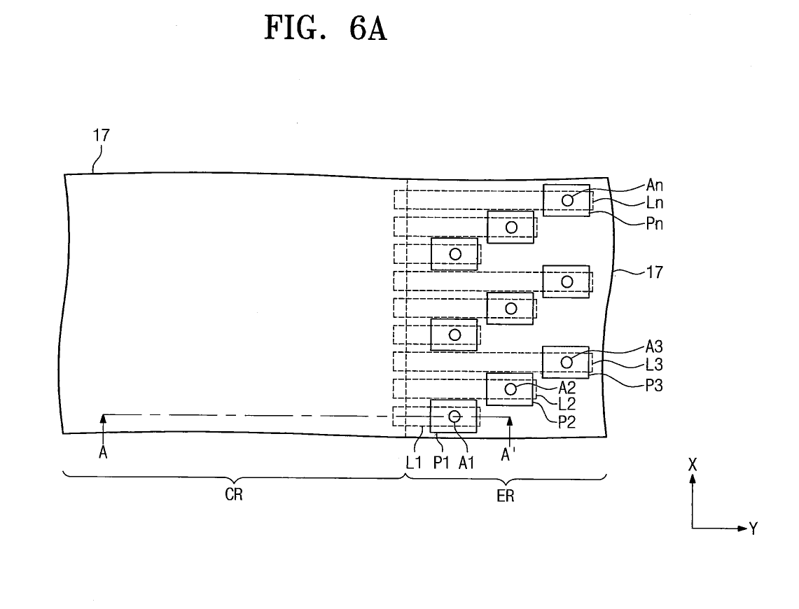

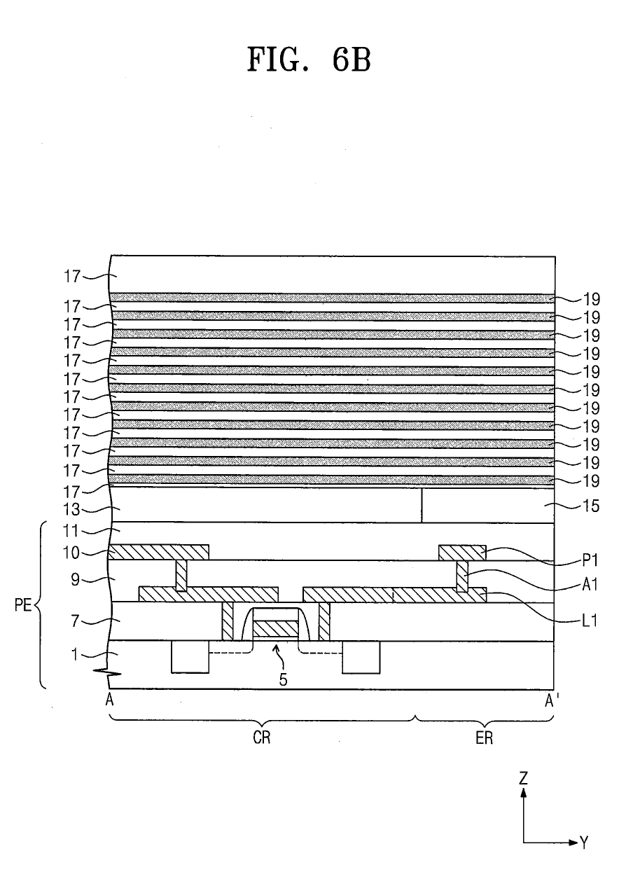

Referring to FIGS. 6A and 6B, intergate insulating layers 17 and sacrificial layers 19, which are alternately stacked on the semiconductor layer 13, and the fourth interlayer insulating layer 15 may be formed. The sacrificial layers 19 may be formed of a material having an etch selectivity with respect to the intergate insulating layers 17. For example, the intergate insulating layers 17 may be formed of silicon oxide layers, and the sacrificial layers 19 may be formed of silicon nitride layers, poly-silicon layers, or silicon-germanium layers.

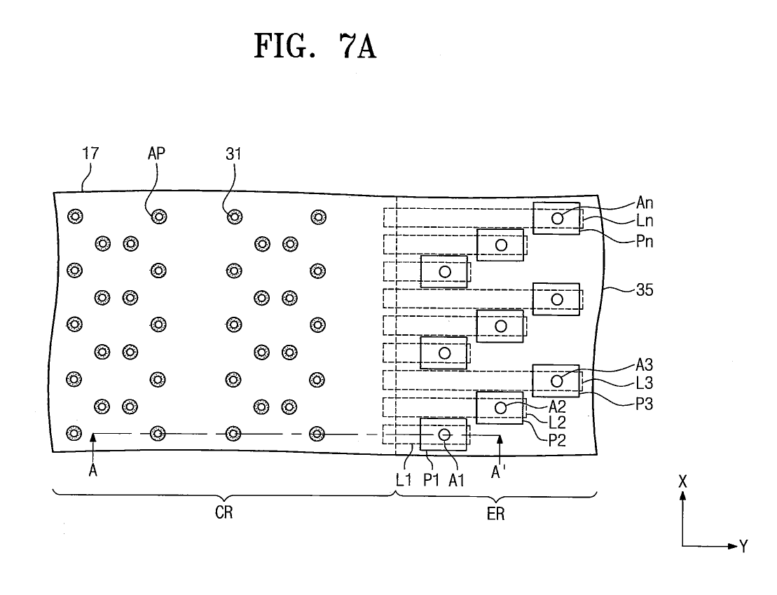

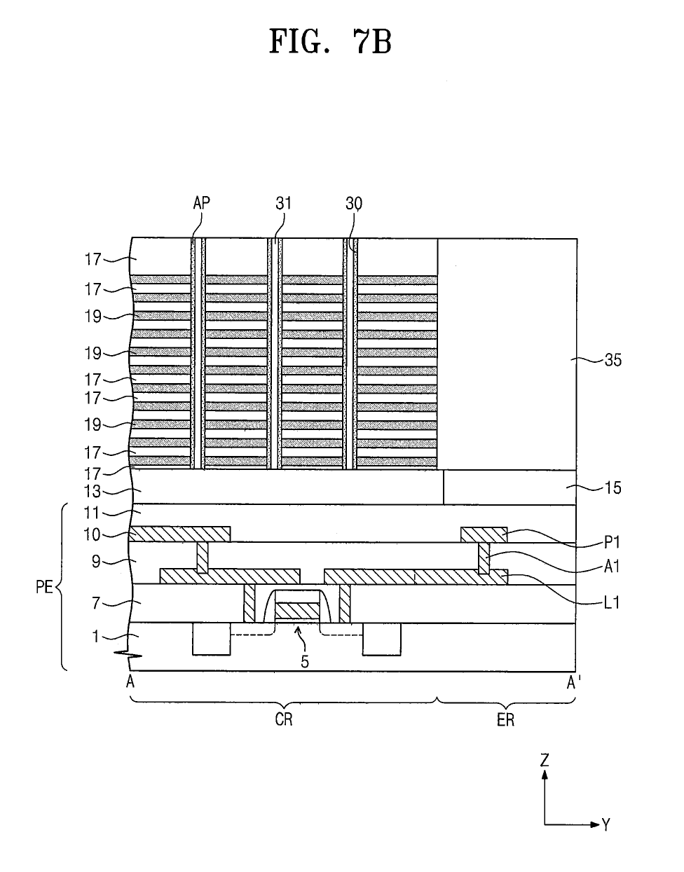

Referring to FIGS. 7A and 7B, active holes 30 may be formed to penetrate the intergate insulating layers 17 and the sacrificial layers 19 in the circuit region CR, and active pillars AP may be formed in the active holes 30, respectively. The active pillars AP may be in contact with the semiconductor layer 13. A first filling insulation pattern 31 may be formed to fill an inner space of each of the active pillars AP. The intergate insulating layers 17 and the sacrificial layers 19 disposed in the connection region ER may be removed. For the purpose of ease and convenience in explanation, FIGS. 7A and 7B illustrate sidewalls of the intergate insulating layers 17 and the sacrificial layers 19 which are adjacent to the connection region ER and vertically aligned with one another. However, the inventive concept is not limited thereto. In some embodiments, the sidewalls of the intergate insulating layers 17 and the sacrificial layers 19 may form a stepped structure. A fifth interlayer insulating layer 35 may be formed in the connection region ER. The fifth interlayer insulating layer 35 may cover the sidewalls of the intergate insulating layers 17 and the sacrificial layers 19.

As described above, the semiconductor layer 13 in the connection region ER may be removed in the step described with reference to FIGS. 5A and 5B. In some embodiments, the semiconductor layer 13 of the connection region ER may be removed when the intergate insulating layers 17 and the sacrificial layers 19 disposed in the connection region ER are etched. In some embodiments, the fourth interlayer insulating layer 15 may be omitted, and the fifth interlayer insulating layer 35 may cover the sidewall of the semiconductor layer 13 adjacent to the connection region ER.

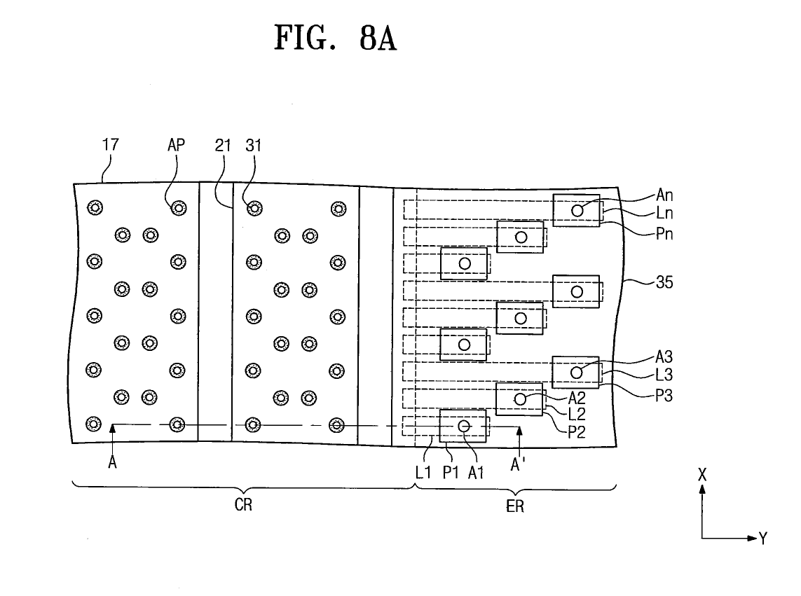

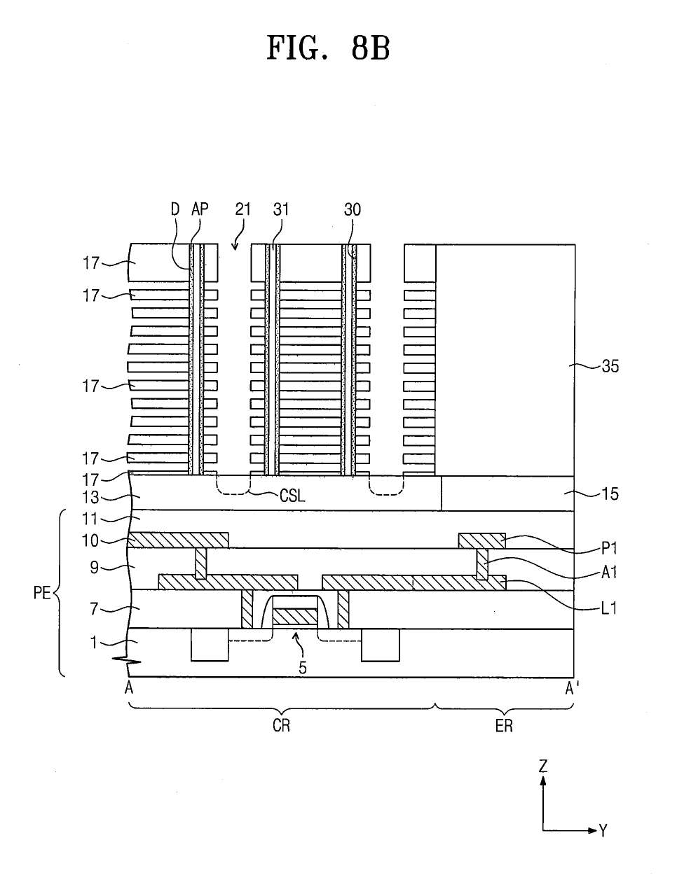

Referring to FIGS. 8A and 8B, the intergate insulating layers 17 and sacrificial layers 19 disposed in the circuit region CR may be patterned to form grooves 21 exposing the semiconductor layer 13. The grooves 21 may be spaced apart from the active pillars AP. The sacrificial layers 19 may be selectively removed through the grooves 21 to form empty regions between the intergate insulating layers 17. An ion implantation process may be performed to form common source regions CSL in the semiconductor layer 13 exposed by the grooves 21. At this time, a common drain region D may be formed in a top end portion of each of the active pillars AP.

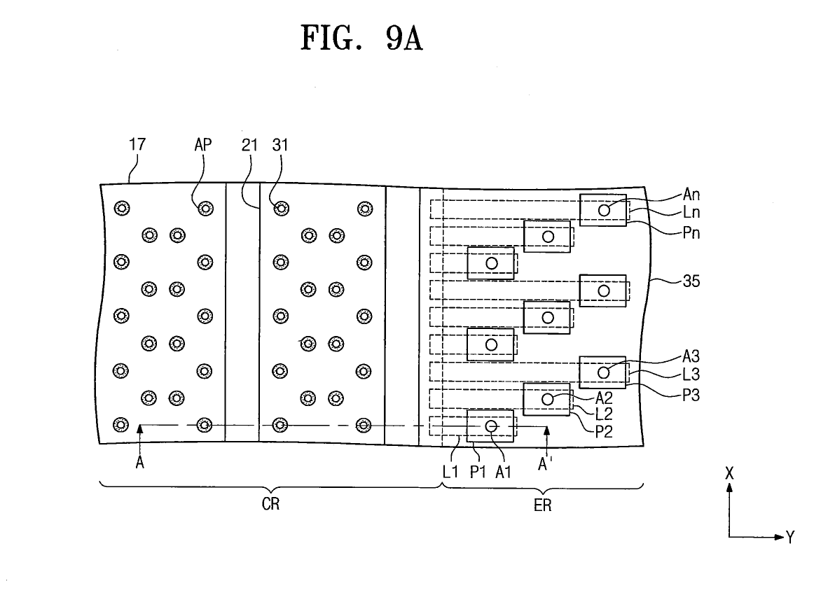

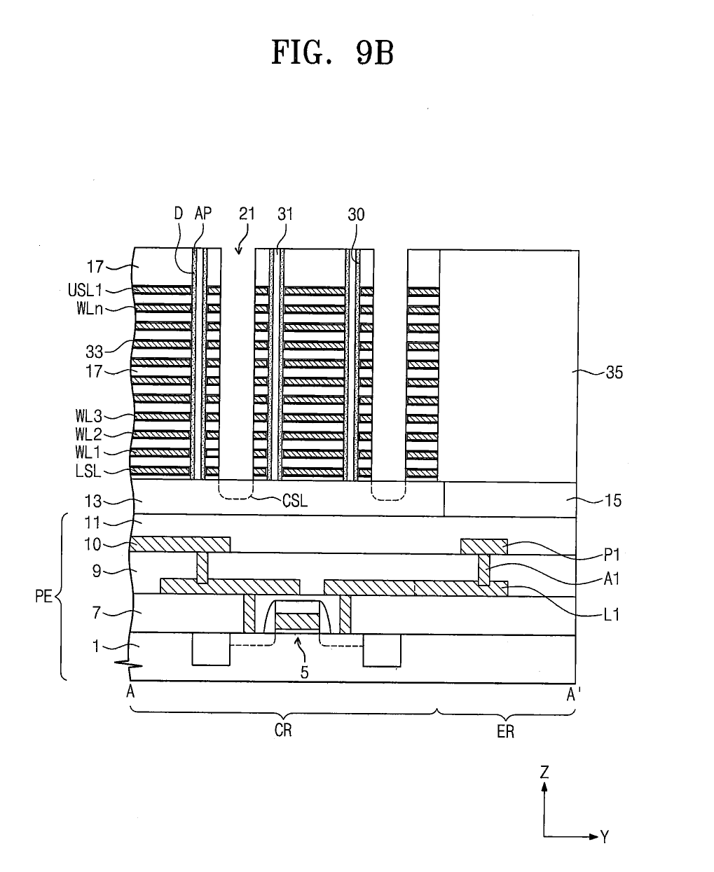

Referring to FIGS. 9A and 9B, a gate dielectric layer 33 may be conformally formed in the empty regions and a conductive layer may be formed on the gate dielectric layer 33 to fill the empty regions. Thereafter, the conductive layer disposed outside the empty regions may be removed to form lower selection lines LSL, word lines WL1 to WLn, and upper selection lines USL1 to USLn in the empty regions. At least a portion of the gate dielectric layer 33 may be formed in advance on a sidewall of the active hole 30 before the active pillar AP is formed.

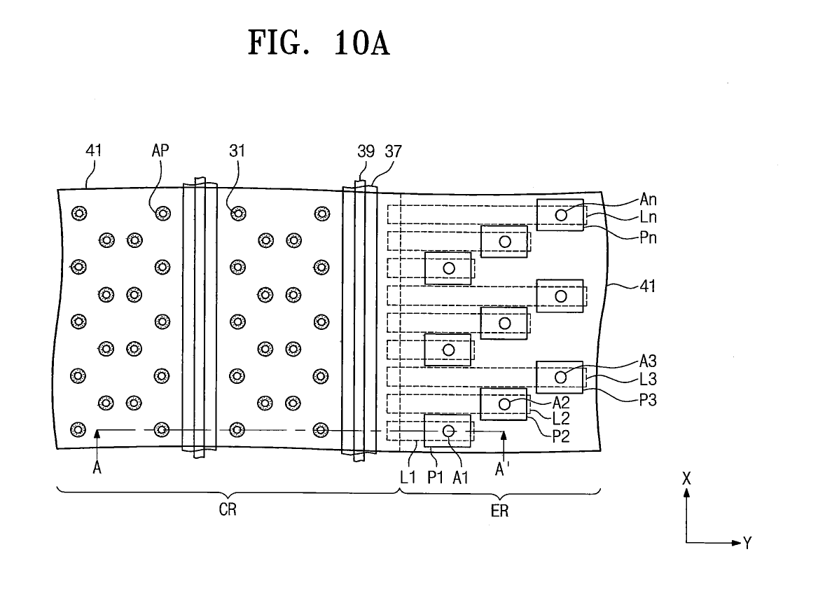

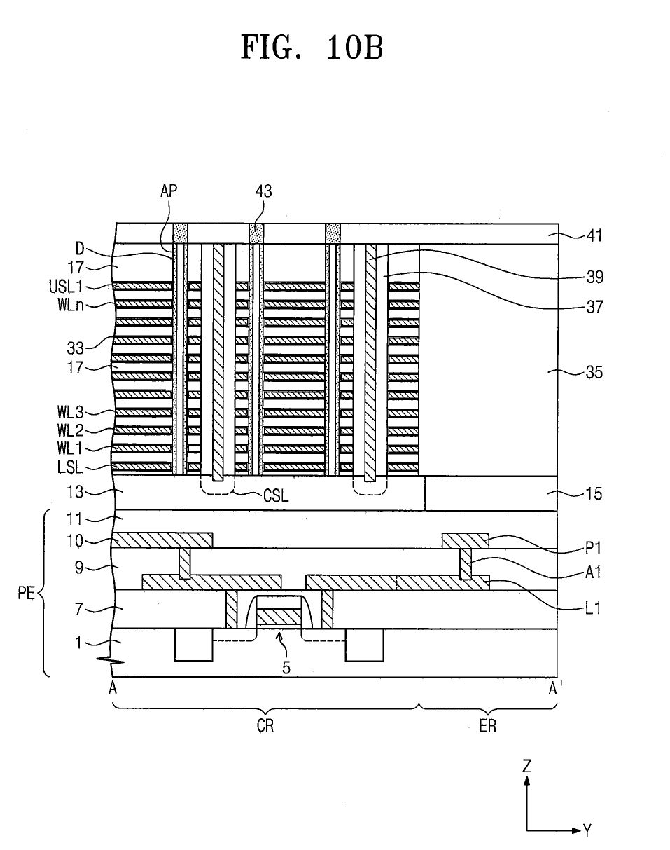

Referring to FIGS. 10A and 10B, a second filling insulation pattern 37 may be formed to cover an inner sidewall of each of the grooves 21. Thereafter, a common source interconnection 39 may be formed in each of the grooves 21. The common source interconnection 39 may be connected to the common source line CSL. A sixth interlayer insulating layer 41 may be formed on the uppermost intergate insulating layer 17 and the fifth interlayer insulating layer 35. Active plugs 43 may be formed to penetrate the sixth interlayer insulating layer 41. The active plugs 43 may be in contact with the active pillars AP, respectively.

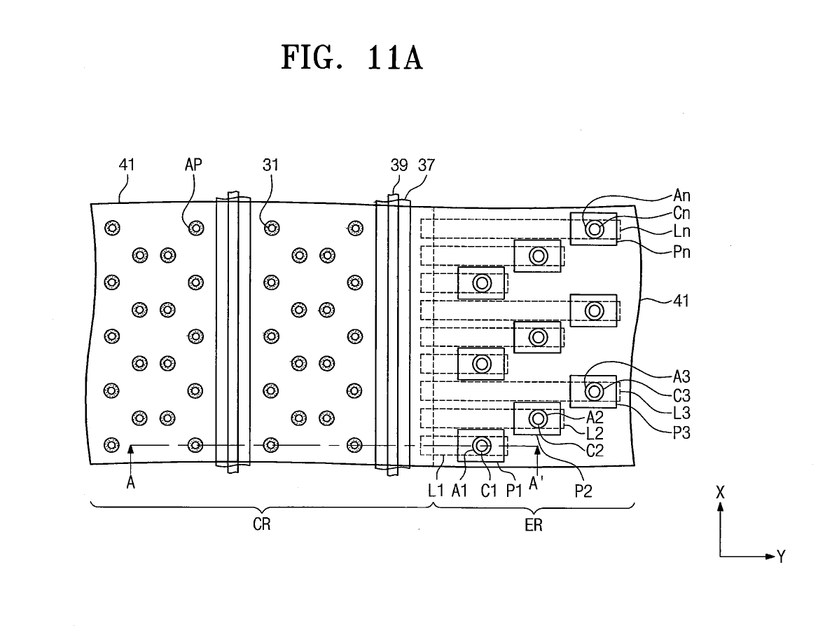

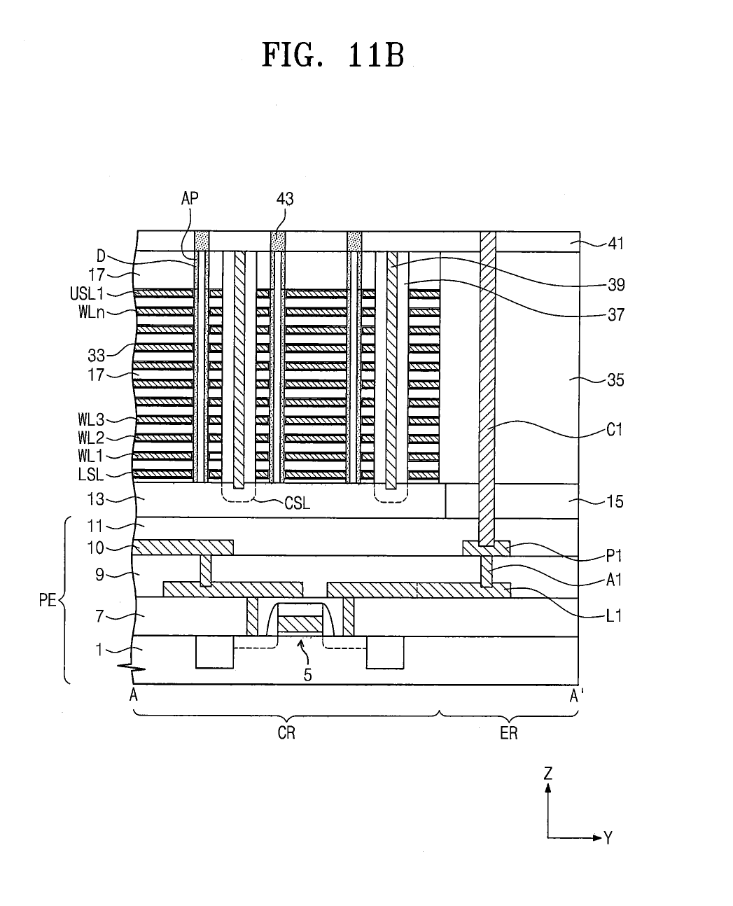

Referring to FIGS. 11A and 11B, deep contacts C1 to Cn may be formed to penetrate the sixth interlayer insulating layer 41, the fifth interlayer insulating layer 35, the fourth interlayer insulating layer 15, and the third interlayer insulating layer 11 in the connection region ER. The deep contacts C1 to Cn may be in contact with the connection pads P1 to Pn, respectively.

Referring again to FIGS. 2A and 2B, a seventh interlayer insulating layer 45 may be formed on the sixth interlayer insulating layer 41. Bit line contacts 47 may be formed in the seventh interlayer insulating layer 45 in the circuit region CR. The bit line contacts 47 may be connected to the active plugs 43, respectively. Upper assistant connection contacts B1 to Bn may be formed in the seventh interlayer insulating layer 45 in the connection region ER. The upper assistant connection contacts B1 to Bn may be connected to the deep connection contacts C1 to Cn. Bit lines BL1 to BLn may be formed on the seventh interlayer insulating layer 45. The bit lines BL1 to BLn, the bit line contacts 47, and the upper assistant connection contacts B1 to Bn may be formed at the same time. In some embodiments, the bit lines BL1 to BLn, the bit line contacts 47, and the upper assistant connection contacts B1 to Bn may be formed concurrently.

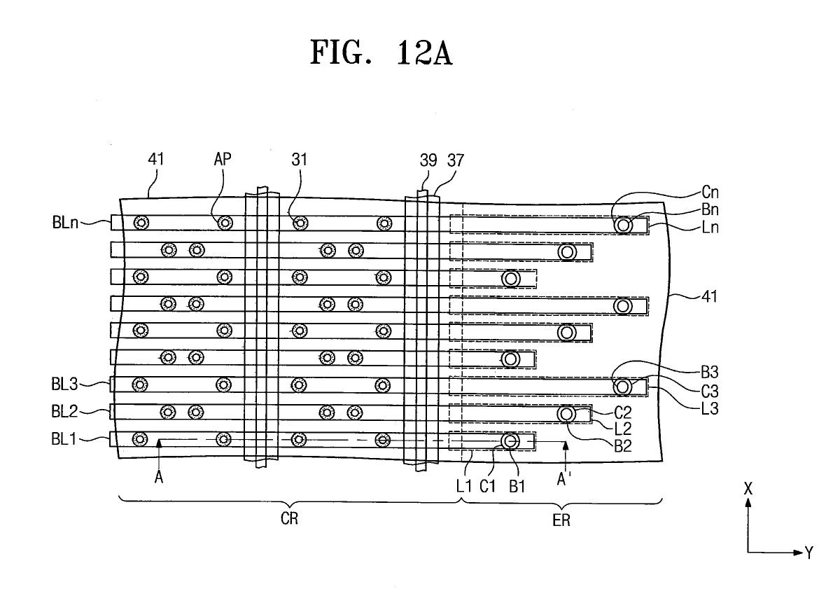

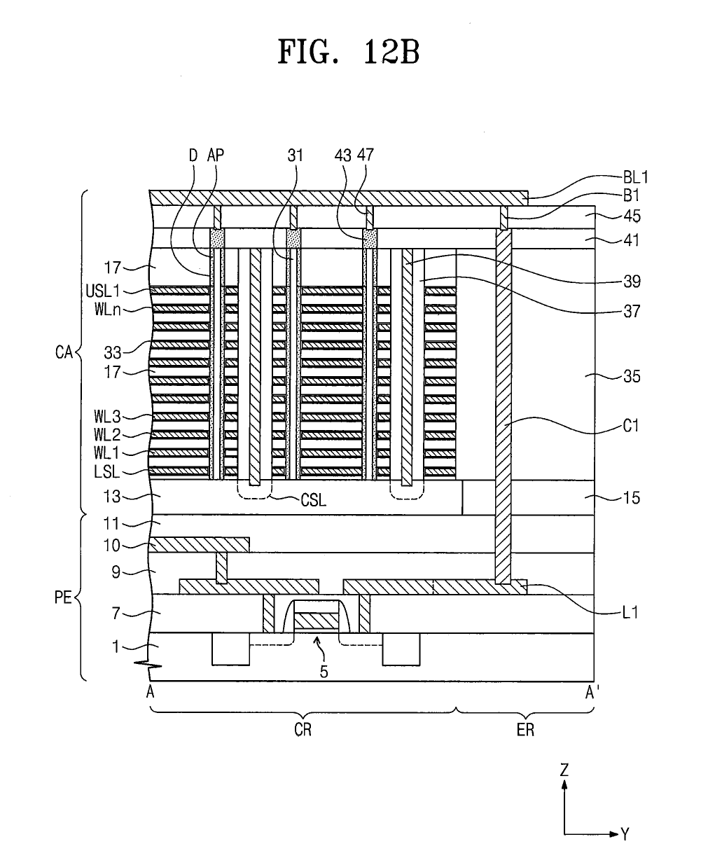

FIG. 12A is a plan view illustrating a semiconductor device according to some embodiments of the inventive concept, and FIG. 12B is a cross-sectional view taken along the line A-A′ of FIG. 12A.

Referring to FIGS. 12A and 12B, a semiconductor device according to some embodiments may not include the lower assistant connection contacts A1 to An and the connection pads P1 to Pn illustrated in FIGS. 2A and 2C. Deep connection contacts C1 to Cn may penetrate the second to sixth interlayer insulating layers 9, 11, 13, 35, and 41 so as to be in direct contact with the connection lines L1 to Ln, respectively. Other elements of the semiconductor device of FIGS. 12A and 1213 may be the same as or similar to corresponding elements of the semiconductor device described with reference to FIGS. 2A and 2B.

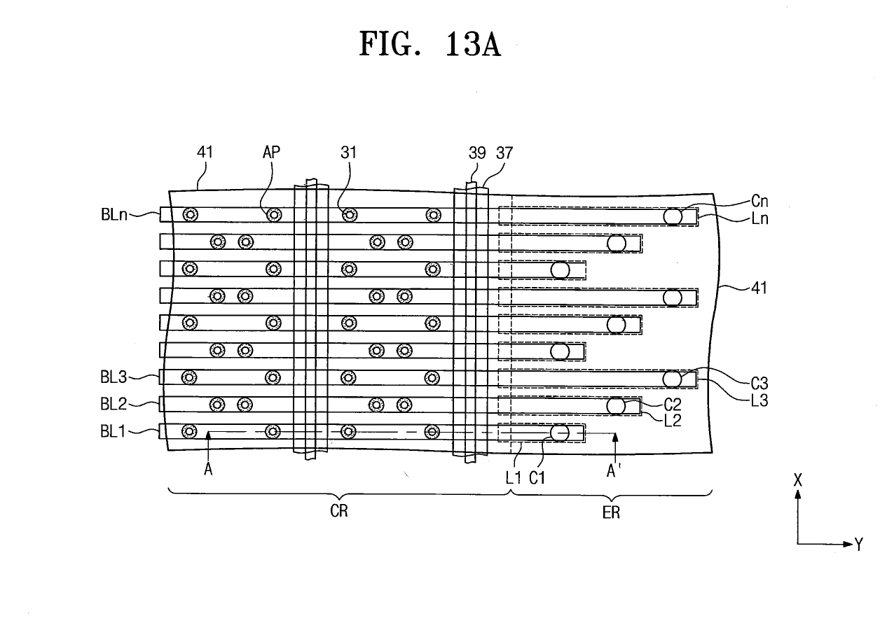

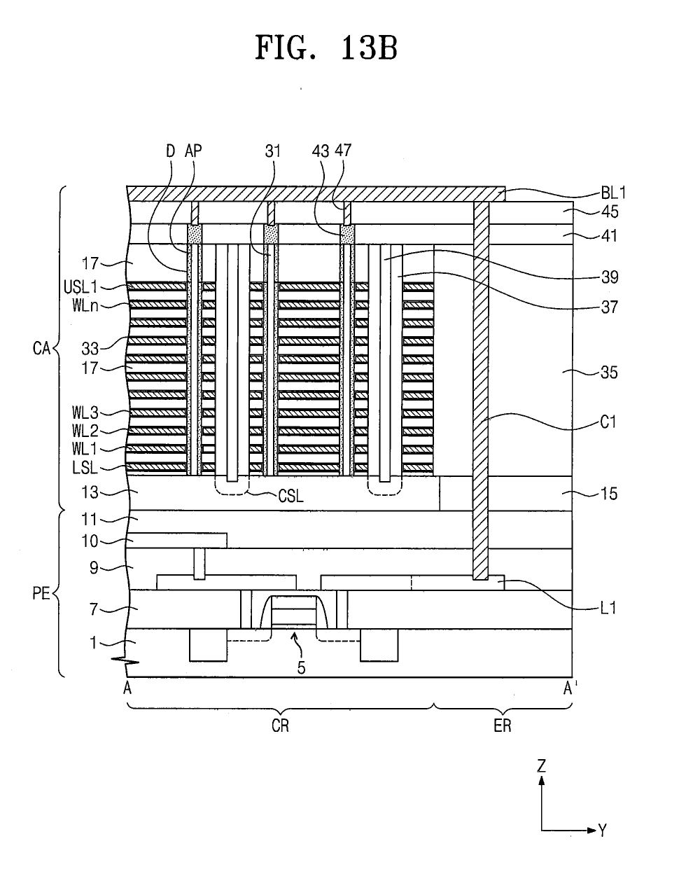

FIG. 13A is a plan view illustrating a semiconductor device according to some embodiments of the inventive concept, and FIG. 1313 is a cross-sectional view taken along the line A-A′ of FIG. 13A.

Referring to FIGS. 13A and 13B, a semiconductor device according to some embodiments may not include the lower assistant connection contacts A1 to An, the connection pads P1 to Pn, and the upper assistant connection contacts B1 to Bn illustrated in FIGS. 2A and 213. Deep connection contacts C1 to Cn may penetrate the second to seventh interlayer insulating layers 9, 11, 13, 35, 41, and 45 so as to be in direct contact with the connection lines L1 to Ln, respectively. Other elements of the semiconductor device of FIGS. 13A and 13B may be the same as or similar to corresponding elements of the semiconductor device described with reference to FIGS. 2A and 2B.

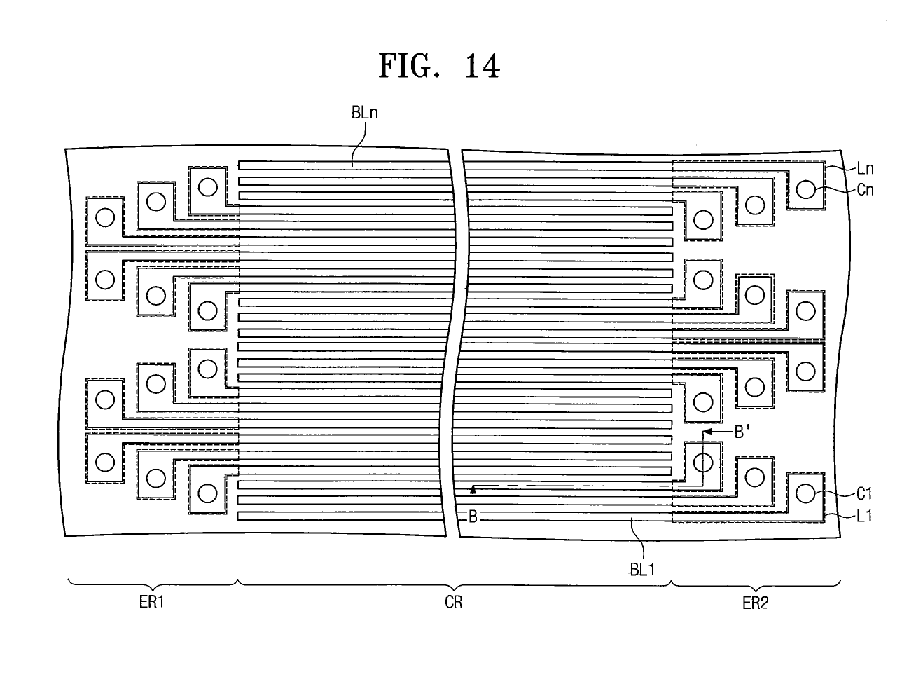

FIG. 14 is a plan view illustrating a semiconductor device according to some embodiments of the inventive concept.

Referring to FIG. 14, a semiconductor may include a first connection region ER1 and a second connection region ER2, which may be disposed at both sides of a circuit region CR, respectively. In FIG. 14, the active pillars AP and the common source interconnection 39 are omitted to give prominence to features of the embodiment illustrated in FIG. 14. However, a cross-sectional view taken along the line B-B′ of FIG. 14 may be the same as or similar to the cross-sectional view of FIG. 13B. Some of the bit lines BL1 to BLn may extend into the first connection region ER1, and the others of the bit lines BL1 to BLn may extend into the second connection region ER2. End portions of the bit lines BL1 to BLn that are disposed in the connection regions ER1 and ER2 may be wider than line portions of the bit lines BL1 to BLn that are disposed in the circuit region CR. The end portions of the bit lines BL1 to BLn may have bent shapes. In each of the first and second connection regions ER1 and ER2, some and others of the bit lines BL1 to BLn may be symmetric and be repeatedly arranged. In the connection regions ER1 and ER2, shapes and positions of connection lines L1 to Ln may be changed to correspond to the shapes and positions of the bit lines BL1 to BLn. Thus, the deep connection contacts C1 to Cn may be easily formed without the assistant connection contacts A1 to An and B1 to Bn and the connection pads P1 to Pn of FIGS. 2A and 2B. Other elements of the semiconductor device of FIG. 14 may be the same as or similar to corresponding elements of the semiconductor device described with reference to FIGS. 13A and 13B.

The features of the semiconductor device of FIG. 14 may be used in the semiconductor devices illustrated in FIGS. 2B and 12B.

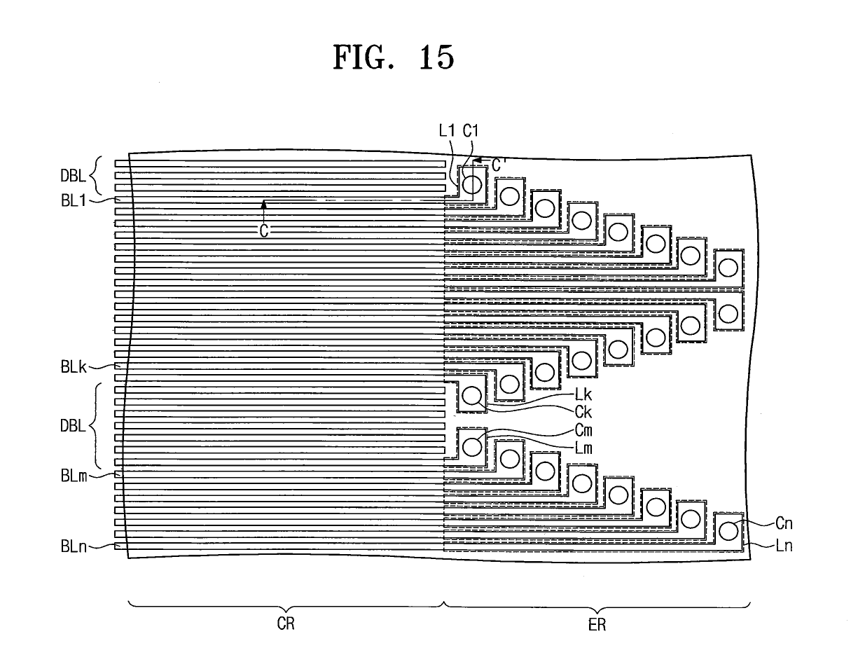

FIG. 15 is a plan view illustrating a semiconductor device according to some embodiments of the inventive concept.

Referring to FIG. 15, a semiconductor device according to some embodiments may include a first group consisting of bit lines BL1 to BLk, a second group consisting of bit lines BLm to BLn, and dummy bit lines DBL disposed between the first group and the second group. The second group may be adjacent to the first group. End portions of the dummy bit lines DBL may not extend into a connection region ER. In other words, the dummy bit lines DBL may be locally disposed in the circuit region CR. In some embodiments, the dummy bit lines DBL may be disposed only in the circuit region CR. In FIG. 15, the active pillars AP and the common source interconnection 39 are omitted to highlight features of the embodiment illustrated in FIG. 15. However, a cross-sectional view taken along the line C-C′ of FIG. 15 may be the same as or similar to the cross-sectional view of FIG. 13B. End portions of the bit lines BL1 to BLk and BLm to BLn may have bent shapes. In addition, some and others of the bit lines BL1 to BLk and BLm to BLn may be symmetric and be repeatedly arranged. In the connection region ER, shapes and positions of connection lines L1 to Ln may be changed to correspond to the shapes and positions of the bit lines BL1 to BLn. Thus, the deep connection contacts C1 to Cn may be easily formed without the assistant connection contacts A1 to An and B1 to Bn and the connection pads P1 to Pn of FIGS. 2A and 2B. Other elements of the semiconductor device of FIG. 15 may be the same as or similar to corresponding elements of the semiconductor device described with reference to FIGS. 13A and 13B.

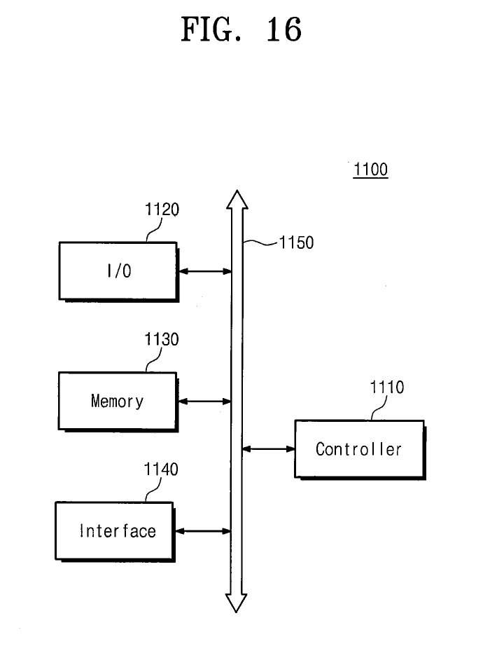

FIG. 16 is a schematic block diagram illustrating a memory system including a semiconductor device according to some embodiments of the inventive concept.

Referring to FIG. 16, a memory system 1100 may be used in a personal digital assistant (PDA), a portable computer, a web tablet, a wireless phone, a mobile phone, a digital music player, a memory card, or other electronic products receiving or transmitting information data by wireless.

The memory system 1100 may include a controller 1110, an input/output (I/O) unit 1120, a memory device 1130, an interface unit 1140, and a data bus 1150. At least two of the controller 1110, the I/O unit 1120, the memory device 1130, and the interface unit 1140 may communicate with each other through the data bus 1150.

The controller 1110 may include at least one of a microprocessor, a digital signal processor, a microcontroller, or other logic devices. Functions of the other logic devices may be a similar to those of the microprocessor, the digital signal processor and the microcontroller. The memory device 1130 may store commands that are to be executed by the controller 1110. The I/O unit 1120 may receive data or signals from an external system or may output data or signals to the external system. For example, the I/O unit 1120 may include a keypad, a keyboard and/or a display device.

The memory device 1130 may include at least one of the non-volatile memory devices according to some embodiments of the inventive concept. The memory device 1130 may further include at least one of another type of semiconductor memory devices and volatile random access memory devices.

The interface unit 1140 may transmit electrical data to a communication network or may receive electrical data from a communication network.

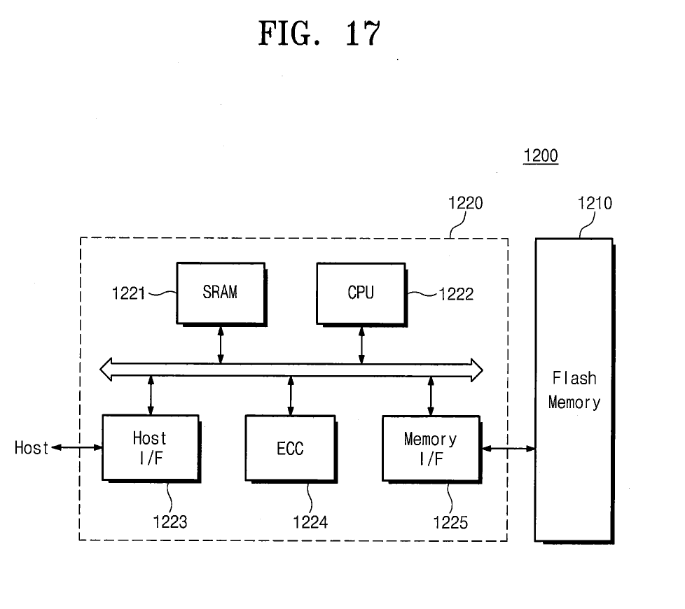

FIG. 17 is a schematic block diagram illustrating a memory card including a semiconductor device according to some embodiments of the inventive concept.

Referring to FIG. 17, a memory card 1200 for storing high-capacity data may include a flash memory device 1210 implemented with at least one of the semiconductor devices according to embodiments of the inventive concept. The memory card 1200 may further include a memory controller 1220 that controls data communication between a host and the flash memory device 1210.

A static random access memory (SRAM) device 1221 may be used as a working memory of a central processing unit (CPU) 1222. A host interface unit 1223 may be configured to include a data communication protocol between the data storage device 1200 and the host. An error check and correction (ECC) block 1224 may detect and correct errors of data which are read out from the flash memory device 1210. A memory interface unit 1225 may interface with the flash memory device 1210. The CPU 1222 may control overall operations of the memory controller 1220 for exchanging data. Even though not shown in the drawings, the memory card 1200 may further include a read only memory (ROM) storing code data for interfacing with the host.

The memory system or the memory card may be realized as a solid state disk (SSD).

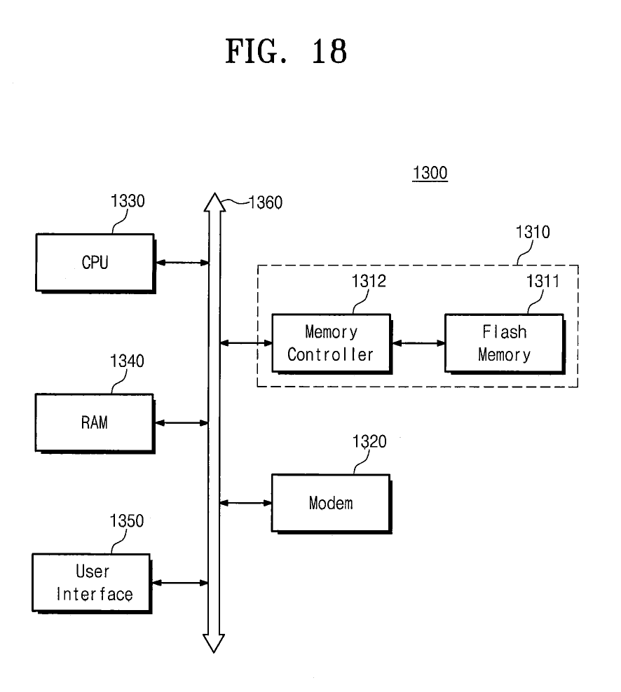

FIG. 18 is a schematic block diagram illustrating an information processing system including a semiconductor device according to some embodiments of the inventive concept.

Referring to FIG. 18, an information processing system 1300 (e.g., a mobile device or a desk top computer) may include a flash memory system 1310 implemented with at least one of the semiconductor devices according to embodiments of the inventive concept. The flash memory system 1310 may include a flash memory 1311 and a memory controller 1312. The information processing system 1300 may further include a modem 1320, a central processing unit (CPU) 1330, a random access memory (RAM) device 1340, and a user interface unit 1350 which are electrically connected to the flash memory system 1310 through a system bus 1360. The flash memory system 1310 may be substantially the same as the memory system or the memory card described above. The flash memory system 1310 may store data inputted from an external system and/or data processed by the CPU 1330. In some embodiments, the flash memory system 1310 may be realized as a solid state disk (SSD). In this case, the information processing system 1330 may stably store massive data into the flash memory system. In addition, as reliability of the flash memory system 1310 may increase, the flash memory system 1310 may reduce a resource consumed for correcting errors. Even though not shown in the drawings, an application chipset, a camera image processor (CIS), and an input/output unit may further be provided in the information processing system 1300.

The semiconductor devices and/or the memory system according to some embodiments of the inventive concept may be encapsulated using various packaging techniques. For example, the semiconductor devices and/or the memory system according to the aforementioned embodiments may be encapsulated using any one of a package on package (POP) technique, a ball grid arrays (BGAs) technique, a chip scale packages (CSPs) technique, a plastic leaded chip carrier (PLCC) technique, a plastic dual in-line package (PDIP) technique, a die in waffle pack technique, a die in wafer form technique, a chip on board (COB) technique, a ceramic dual in-line package (CERDIP) technique, a plastic metric quad flat package (PMQFP) technique, a plastic quad flat package (PQFP) technique, a small outline package (SOP) technique, a shrink small outline package (SSOP) technique, a thin small outline package (TSOP) technique, a thin quad flat package (TQFP) technique, a system in package (SIP) technique, a multi-chip package (MCP) technique, a wafer-level fabricated package (WFP) technique and a wafer-level processed stack package (WSP) technique.

In semiconductor devices according to embodiments of the inventive concept, the peripheral circuit part may be disposed under the cell array circuit part, thereby increasing an integration degree of the semiconductor device. In addition, first conductive lines connected to the peripheral circuit part respectively may have substantially the same shapes as second conductive lines connected to the cell array circuit part in the connection region, and thus, it is easy to connect the first conductive lines to the second conductive lines. In other words, it is possible to easily realize the highly integrated semiconductor device.

The above-disclosed subject matter is to be considered illustrative, and not restrictive, and the appended claims are intended to cover all such modifications, enhancements, and other embodiments, which fall within the true spirit and scope of the inventive concept. Thus, to the maximum extent allowed by law, the scope is to be determined by the broadest permissible interpretation of the following claims and their equivalents, and shall not be restricted or limited by the foregoing detailed description.

What is claimed is:

1. A semiconductor device comprising:
a substrate comprising a circuit region and a first connection region disposed at a side of the circuit region;
a peripheral circuit part disposed on the substrate in the circuit region;
first conductive lines electrically connected to the peripheral circuit part and extending into the first connection region;
a cell array circuit part disposed on the peripheral circuit part;
second conductive lines electrically connected to the cell array circuit part and disposed above the first conductive lines; and
first conductive contacts connecting the second conductive lines to the first conductive lines, respectively,
wherein the first conductive lines and the second conductive lines have substantially equal shapes, and the first conductive lines overlap with the second conductive lines in the first connection region, respectively, when viewed from a plan view.

2. The semiconductor device of claim 1, wherein the cell array circuit part comprises:
a semiconductor layer insulated from the peripheral circuit part;
active pillars protruding from the semiconductor layer; and
word lines adjacent to a sidewall of each of the active pillars, the word lines extending in a direction intersecting the second conductive lines,
wherein the second conductive lines are bit lines that are electrically connected to top ends of the active pillars.

3. The semiconductor device of claim 2, further comprising:
a first interlayer insulating layer covering a sidewall of the cell array circuit part and the first conductive lines,
wherein the first conductive contacts pass through the first interlayer insulating layer.

4. The semiconductor device of claim 3, further comprising:
a second interlayer insulating layer covering the active pillars and the first interlayer insulating layer, wherein the second interlayer insulating layer is thinner than the first interlayer insulating layer; and
second conductive contacts passing through the second interlayer insulating layer and connecting the first conductive contacts to the second conductive lines, respectively,
wherein widths of the second conductive contacts are smaller than widths of the first conductive contacts.

5. The semiconductor device of claim 3, further comprising:
a second interlayer insulating layer disposed between the semiconductor layer and the first conductive lines and between the first interlayer insulating layer and the first conductive lines; and
second conductive contacts passing through the second interlayer insulating layer and connecting the first conductive contacts to the first conductive lines, respectively,
wherein widths of the second conductive contacts are smaller than widths of the first conductive contacts.

6. The semiconductor device of claim 5, further comprising:
conductive pads disposed between the second conductive contacts and the first conductive contacts, respectively,
wherein widths of the conductive pads are greater than the widths of the first conductive contacts.

7. The semiconductor device of claim 1, wherein the first conductive lines and the second conductive lines have substantially equal widths.

8. The semiconductor device of claim 1, wherein a first one of the first conductive lines laterally protrudes more than a second one of the first conductive lines that is adjacent to the first one of the first conductive lines, and
wherein a first one of the second conductive lines laterally protrudes more than a second one of the second conductive lines that is adjacent to the first one of the second conductive lines.

9. The semiconductor device of claim 8, wherein widths of end portions of the first and second conductive lines are greater than widths of line portions of the second conductive lines.

10. The semiconductor device of claim 8, wherein end portions of the first and second conductive lines are bent in a direction intersecting a longitudinal direction of the second conductive lines.

11. The semiconductor device of claim 9, wherein the substrate further comprises a second connection region disposed at another side of the circuit region, the second connection region being opposite to the first connection region such that the circuit region is disposed between the first connection region and the second connection region,
wherein first ones of the end portions of the first and second conductive lines are disposed above the substrate of the first connection region and second ones of the end portions of the first and second connection lines are disposed above the substrate of the second connection region.

12. The semiconductor device of claim 9, further comprising:
a dummy conductive line disposed between the second conductive lines adjacent to each other, the dummy conductive line extending parallel to the second conductive lines.

13. The semiconductor device of claim 12, wherein the dummy conductive line does not extend into the first connection region.

14. The semiconductor device of claim 12, wherein the dummy conductive line does not overlap with the first conductive lines.

15. The semiconductor device of claim 1, wherein first ones of the first and second conductive lines and second ones of first and second conductive lines are symmetric in the first connection region.

16. A semiconductor device comprising:
a substrate comprising a circuit region and a connection region disposed at a side of the circuit region;
a page buffer disposed on the substrate in the circuit region;
first and second connection lines electrically connected to the page buffer and extending into the connection region in a first direction that is parallel to a top surface of the substrate;
a plurality of vertical cell strings disposed on the page buffer;
first and second bit lines electrically connected to the vertical cell strings and disposed above the first and second connection lines, respectively; and
first and second connection contacts connecting the first and second bit lines to the first and second connection lines, respectively,
wherein the first and second connection lines overlap with the first and second bit lines in the connection region, respectively, when viewed from a plan view,
wherein the second connection line laterally protrudes more than the first connection line in the first direction, and the second bit line laterally protrudes more than the first bit line in the first direction.

17. The semiconductor device of claim 16, wherein the first and second connection lines have substantially equal widths to the first and second bit lines, respectively.

18. The semiconductor device of claim 16, further comprising:
third and fourth connection lines adjacent to and spaced apart from the first and second connection lines in a second direction intersecting the first direction; and
third and fourth bit lines adjacent to and spaced apart from the first and second bit lines in the second direction,
wherein the first and second connection lines and the third and fourth connection lines are symmetric in the connection region, and
wherein the first and second bit lines and the third and fourth bit lines are symmetric in the connection region.

19. The semiconductor device of claim 16, wherein widths of end portions of the first and second connection lines and the first and second bit lines are greater than widths of line portions of the first and second bit lines.

20. The semiconductor device of claim 16, wherein end portions of the first and second connection lines and the first and second bit lines are bent in a second direction intersecting the first direction.
